(19) United States
(12) Patent Application Publication
(10) Pub. No.: US 2026/0190742 A1
(43) Pub. Date: Jul. 2, 2026

(54) DISPLAY DEVICE

(71) Applicant: LG Display Co., Ltd., Seoul (KR)

(72) Inventors: In Tae KO, Paju-si (KR); Hyun Jik BAE, Paju-si (KR)

(21) Appl. No.: 19/396,597

(22) Filed: Nov. 21, 2025

(30) Foreign Application Priority Data
Dec. 27, 2024 (KR) 10-2024-0199380

(51) Int. Cl. H10K 59/40; G06F 3/044; H10K 59/122; H10K 59/38; H10K 59/80

(52) U.S. Cl. CPC H10K 59/40; G06F 3/0445; H10K 59/122; H10K 59/38; H10K 59/873; H10K 59/8792; G06F 2203/04111

(57) ABSTRACT

A display device includes a substrate having a plurality of emission areas and a plurality of transmissive areas spaced apart from each other, a light-emitting element on the substrate, an encapsulation layer on the light-emitting element, a touch sensor disposed on the encapsulation layer and including a first wiring layer and a second wiring layer that do not overlap with the emission areas and do not overlap with the transmissive areas, the first wiring layer the second wiring layer located at different layers, a light-shielding layer disposed on the touch sensor and overlapping the first wiring layer and the second wiring layer, and a color filter disposed on the touch sensor and overlapping a portion of the light-shielding layer on an outside of the emission areas.

### CROSS REFERENCE TO RELATED APPLICATIONS

Pursuant to 35 U.S.C. § 119(a), this application claims the benefit of an earlier filing date and right of priority to Korean Patent Application No. 10-2024-0199380, filed on Dec. 27, 2024, the entire contents of which are hereby incorporated by reference as if fully set forth herein.

### TECHNICAL FIELD

The present disclosure relates to a display device.

### BACKGROUND

Display devices that display images on TVs, monitors, smartphones, tablets, and laptops are being used in various methods and forms.

These display devices do not require a separate light source, and compactness of devices and clear color display are required. Accordingly, self-luminous display devices such as organic light-emitting display devices and quantum dot light-emitting display devices are being considered as competitive applications.

### SUMMARY

In an aspect of the present disclosure, a display device includes a substrate having a plurality of emission areas and a plurality of transmissive areas spaced apart from each other, a light-emitting element on the substrate, an encapsulation layer on the light-emitting element, a touch sensor disposed on the encapsulation layer and including a first wiring layer and a second wiring layer that do not overlap with the emission areas and do not overlap with the transmissive areas, the first and second wiring layers located at different layers, a light-shielding layer disposed on the touch sensor and overlapping the first wiring layer and the second wiring layer, and a color filter on the touch sensor and overlapping a portion of the light-shielding layer on the outside of the emission areas.

In addition, the display device may include a first contact hole located at a corner of at least one emission area having a polygonal shape among the plurality of emission areas and disposed between the first wiring layer and the second wiring layer.

It is to be understood that both the foregoing general description and the following detailed description of the present disclosure are examples and explanatory and are intended to provide further explanation of the present disclosure as claimed.

### BRIEF DESCRIPTION OF THE DRAWINGS

The accompanying drawings, which are included to provide a further understanding of the present disclosure and are incorporated in and constitute a part of this application, illustrate implementation(s) of the present disclosure and together with the description serve to explain the principle of the present disclosure. In the drawings:

FIG. 1 is a plan view showing an example of a display device according to an implementation of the present disclosure;

FIG. 2 is a circuit diagram showing an example of a subpixel according to an implementation of the present disclosure;

FIG. 3 is a plan view showing an example of the arrangement of emission areas and transmissive areas according to an implementation of the present disclosure;

FIG. 4 is an example of a cross-sectional view along lines I-I′ of FIG. 3;

FIG. 5 is an example of a cross-sectional view along lines II-II′ of FIG. 3;

FIG. 6 is a plan view showing an example of a touch sensor of area A in FIG. 3 according to an implementation of the present disclosure;

FIG. 7 is a plan view showing an example of a first wiring layer and a contact hole of area A in FIG. 6;

FIG. 8 is a plan view showing an example of a second wiring layer and a contact hole of area A in FIG. 6; and

FIG. 9 is a plan view showing an example of a light-shielding layer and a color filter of area A in FIG. 6.

### DETAILED DESCRIPTION

The present disclosure relates to a display device, and more specifically, a display device for preventing external light reflection and increasing purity.

In general, a self-luminous display device has a plurality of pixels on a substrate and includes a light-emitting diode having two electrodes facing each other and an emission layer therebetween in each pixel.

Self-luminous display devices can be implemented in transparent display devices that are capable of both emission and transparent display simultaneously.

Implementations of the present disclosure can provide a display device that can increase purity without diffraction or interference of an object or image located on the opposite side of the display surface.

Implementations of the present disclosure can provide a display device that can prevent external light reflection without a separate optical member.

Implementations of the can provide a display device that can minimize parasitic capacitance between wiring layers of a touch sensor in a structure having transmissive areas and improving touch sensitivity.

Implementations of the present disclosure can provide a display device that can prevent glinting caused by a metal wiring layer of a touch sensor from being visible.

Implementations of the present disclosure can also improve ESG (Environmental/Social/Governance) from the viewpoint of improvement of touch sensitivity, pure transmittance, and visibility of a display device.

Additional advantages, aspects, and features of the present disclosure will be set forth in part in the description which follows and in part will become apparent to those having ordinary skill in the art upon examination of the following or may be learned from practice of the present disclosure. The aspects and other advantages of the present disclosure may be realized and attained by the structure particularly pointed out in the written description and claims hereof as well as the appended drawings.

Advantages and features of the disclosure, and implementation methods thereof, will be clarified through the following implementations described with reference to the accompanying drawings. However, the disclosure may be embodied in different forms and should not be construed as limited to the implementations set forth herein. Rather, these implementations are provided so that the disclosure will be thorough and complete, and will fully convey the scope of the disclosure to those skilled in the art. Further, the disclosure is defined only by the categories of the claims.

The same reference numerals designate the same constituent elements. Thicknesses, ratios, and dimensions of constituent elements may be exaggeratedly expressed in the drawings, for effective description of the technical content. In addition, the dimensions and scales of constituent elements shown in the drawings are different from actual dimensions and scales, for convenience of description and, as such, the dimension scales of constituent elements are not limited to those shown in the drawings.

It will be understood that, when one constituent element (or an area, a layer, a portion, or the like) is referred to as being “disposed on”, “connected to” or “coupled to” another constituent element, the one constituent element may be directly connected/coupled to the other constituent element, or a third constituent element may be disposed between the two constituent elements.

The term “and/or” is used to include one or more combinations of associated configurations.

It will be understood that, although the terms “first”, “second”, etc. may be used herein to describe various elements, these elements should not be limited by these terms. These terms are only used to distinguish one element from another. For example, a first element referred to in the following description may represent a second element, without departing from the scope of the disclosure. Similarly, the second element may represent the first element. Unless clearly used otherwise, singular expressions include a plural meaning.

Terms such as “below,” “lower,” “above,” and “upper” are used to describe the relationships between the components shown in the drawings. These terms are relative concepts and are explained based on the orientations indicated in the drawings. For instance, unless “directly” or “immediately” is used, one or more other components may be disposed between two parts. Spatially relative terms such as “below”, “beneath”, “lower,” “above,” and “upper” may be employed to easily describe the correlation between one device or component and other devices or components, as represented in the drawings. These spatially relative terms should be understood as encompassing different orientations of the devices when used or during operation, in addition to the directions shown in the drawings. For example, if the device in one of the drawings is turned over, elements described as “below” or “beneath” other elements would then be oriented “above” the other elements. Therefore, the term “below” may encompass both downward and upward directions.

In this specification, it is to be understood that a term, such as “include” or “have”, is intended to designate that a characteristic, a number, a step, an operation, an element, a part or a combination of them described in the specification is present, and does not preclude the presence or addition possibility of one or more other characteristics, numbers, steps, operations, elements, parts, or combinations thereof.

Features of various implementations of the present disclosure can be partially or overall coupled to or combined with each other, and can be variously inter-operated with each other and driven technically as those skilled in the art can sufficiently understand. The implementations of the present disclosure can be carried out independently from each other, or can be carried out together in a co-dependent relationship.

Hereinafter, a detailed description will be given of a display device according to implementations of the present disclosure in conjunction with the attached drawings.

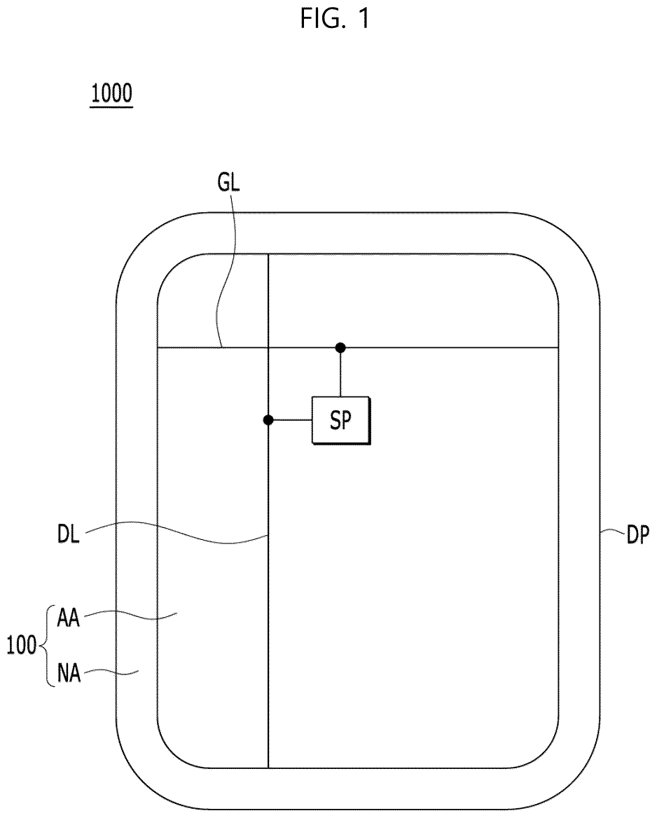

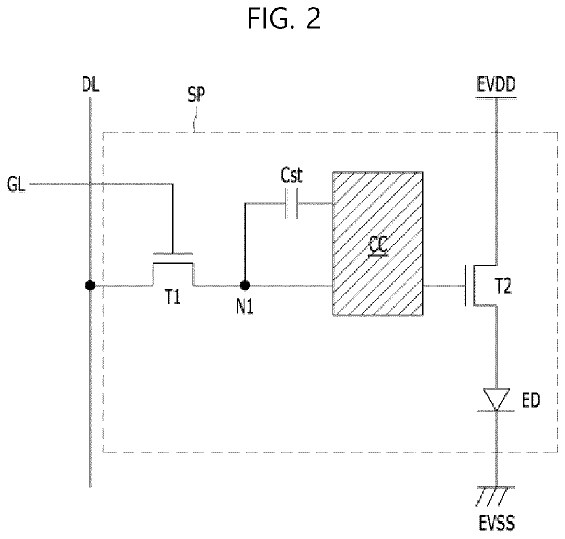

FIG. 1 is a plan view showing an example of a display device according to an implementation of the present disclosure. FIG. 2 is a circuit diagram showing an example of a subpixel according to an implementation of the present disclosure.

Referring to FIG. 1 and FIG. 2, a light-emitting display device 1000 according to an implementation of the present disclosure may include a display panel DP. The display device 1000 can also include a case that accommodates the side of the display panel DP and the lower portion of the display panel DP. A non-active area NA of the display panel DP may be covered by the case or by a separate light-blocking film. A printed circuit film and/or a battery may be provided between the lower portion of the display panel DP and the case.

The display panel DP may include a substrate 100 including an active area AA and a non-active area NA surrounding the active area AA, and a driver connected to the substrate 100. In some implementations, the driver may be formed together with components of an array provided in the active area AA by being integrated into the substrate 111, may be connected to the substrate 100 using COG (Chip On Glass), or may be connected to a printed circuit board through a COF (Chip On Film) type film or connector on the substrate 100. Alternatively, components integrated into the substrate 100 and external components connected using COG or COF may be included as the driver.

The active area AA is an area for displaying an image. A plurality of subpixels SP is disposed in the active area AA of the display panel DP, and an image can be displayed using the plurality of subpixels SP. The non-active area NA is an area other than the active area AA.

The non-active area NA may be disposed, for example, in an edge area surrounding the active area AA for displaying an image. At least one driver for driving the plurality of subpixels SP may be disposed in the non-active area NA. The driver may include a gate-in-panel (GIP). The gate-in-panel (GIP) is connected to a plurality of gate lines GL of the active area AA and may sequentially supply gate voltage signals to the plurality of gate lines GL.

Various additional elements for driving the subpixels SP within the active area AA may be further disposed in the non-active area NA.

At least one of the plurality of subpixels may include a first transistor T1, a second transistor T2, a storage capacitor Cst, a compensation circuit CC, and a light-emitting element ED, as shown in FIG. 2.

For example, the first transistor T1 may be a switching transistor and the second transistor T2 may be a driving transistor.

A first electrode (e.g., a drain electrode) of the first transistor T1 is electrically connected to a data line DL, and a second electrode (e.g., a source electrode) thereof is electrically connected to a first node N1. A gate electrode of the first transistor T1 is electrically connected to a gate line GL. The first transistor T1 transmits a data signal supplied through the data line DL to the first node N1 in response to a scan signal supplied through the gate line GL.

The storage capacitor Cst is electrically connected to the first node N1 and is charged by the voltage applied to the first node N1.

A first electrode (e.g., a drain electrode) of the second transistor T2 receives a high-level driving voltage EVDD, and a second electrode (e.g., a source electrode) thereof is electrically connected to a first electrode (e.g., an anode) of the light-emitting element ED. The second transistor T2 may control the amount of driving current flowing through the light-emitting element ED according to a voltage difference between the gate electrode and the source electrode.

A semiconductor layer of at least one of the first transistor T1 or the second transistor T2 may include silicon such as amorphous silicon (a-Si), polycrystalline silicon (poly-Si), or low-temperature polycrystalline silicon (poly-Si), or may include an oxide semiconductor.

The transistors and display devices of the implementations of the present disclosure may have the advantage of including an oxide semiconductor layer in at least one of the transistors formed on the substrate 111, enabling formation at a relatively low temperature compared to other materials, maintaining amorphous characteristics, and having high mobility.

The light-emitting element ED emits light corresponding to the driving current. One side of the light-emitting element ED is connected to the second transistor T2 and the other side thereof is connected to a first power voltage line through which a ground voltage or a low-level voltage EVSS is supplied, and the light-emitting element ED may emit light corresponding to one of red, green, blue, and white in each subpixel. The ground voltage or the low-level voltage EVSS may be commonly supplied to a second electrode of the light-emitting element ED over subpixels in the active area AA.

The light-emitting element ED may include a first electrode, an organic layer disposed on the first electrode, and a second electrode. The organic layer may include at least one emission layer, and may be implemented to emit light of the same color for each subpixel, such as white light, or may be implemented to emit different colors for subpixels (SP), such as red, green, or blue light when an electric field is formed between the first electrode and the second electrode. In addition to the emission layer, the organic layer may include various types of common layers and functional layers, e.g., to efficiently supply holes and electrons to the emission layer. The second electrode is connected to the first power voltage line through which the low-level voltage EVSS or the ground voltage is supplied. The second transistor T2 (which supplies driving current) is connected to a second power voltage line on the side of the second transistor T2 that is not connected to the light-emitting element ED, through which a high-level voltage EVDD may be supplied to the second transistor T2.

The compensation circuit CC may be additionally provided in the subpixel SP to compensate for the threshold voltage of the second transistor T2. The compensation circuit CC may be composed of one or more transistors. The compensation circuit CC may include one or more transistors and capacitors, and may be configured in various manners depending on the compensation method. The subpixel SP including the compensation circuit CC may include circuits of various structures having different numbers of transistors and/or capacitors, such as 3T1C, 4T2C, 5T2C, 6T1C, 6T2C, 7T1C, and 7T2C.

Among the transistors provided in the subpixel, the switching transistor may require high-speed driving for fast switching operation. The driving transistor may be required to output a high current in order to supply the high current to the light-emitting element to achieve high luminance.

The non-active area NA may include a gate-in-panel (GIP). The gate-in-panel (GIP) outputs gate signals to gate lines according to a gate control signal input from a timing controller, for example. The gate-in-panel (GIP) may include a plurality of transistors, and the plurality of transistors may be formed through the same process as the process for forming the transistors of the subpixel SP.

The display device of the implementations of the present disclosure has both emission areas and transmissive areas in the active area AA to increase the pure transmittance and improve the sensitivity of a touch sensor.

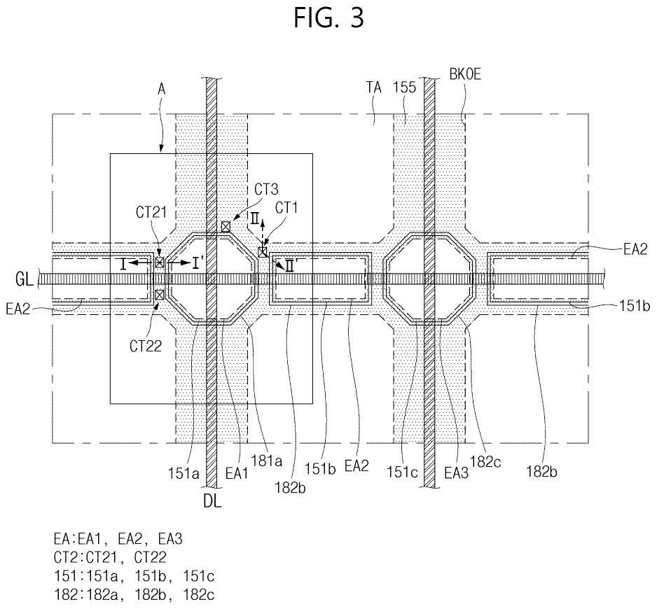

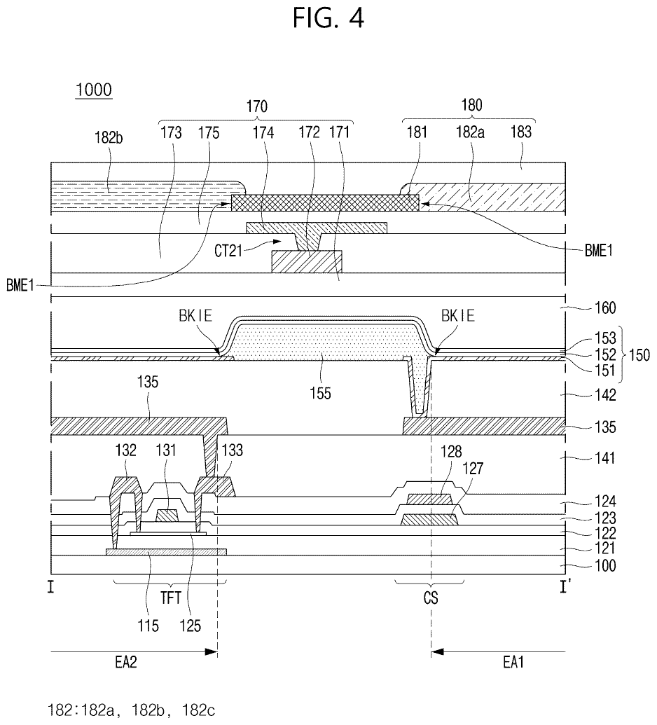

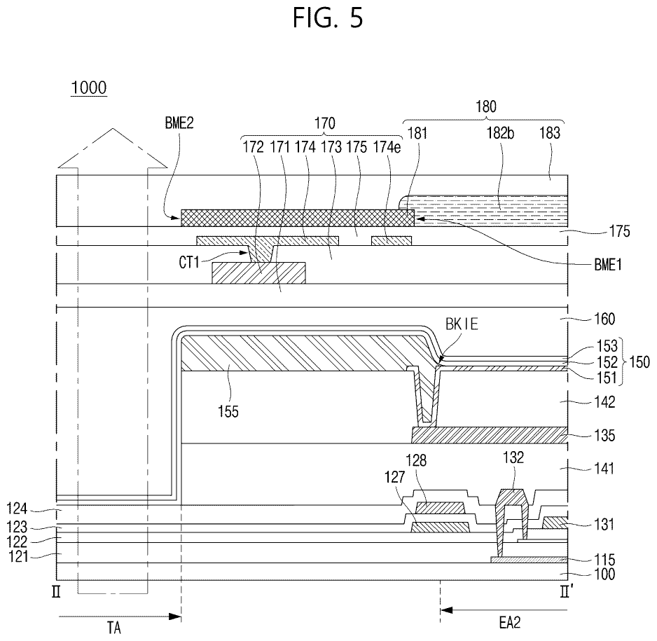

FIG. 3 is a plan view showing an example of the arrangement of emission areas and transmissive areas according to an implementation of the present disclosure. FIG. 4 is an example of a cross-sectional view along the line I-I′ of FIG. 3, and FIG. 5 is an example of a cross-sectional view along the line II-II′ of FIG. 3.

As shown in FIG. 3 to FIG. 5, the display device 1000 according to an implementation of the present disclosure may include a substrate 100 having a plurality of emission areas EA1, EA2, and EA3 and a plurality of transmissive areas TA spaced apart from each other, a light-emitting element 150 provided on the substrate, an encapsulation layer 160 disposed on the light-emitting element 150, a touch sensor 170 including a first wiring layer 172 and a second wiring layer 174 disposed on the encapsulation layer 160 and located on different layers, and a color filter array 180 including a light-shielding layer 181 and color filters 182a and 182b on the touch sensor 170.

The substrate 100 supports and protects components disposed thereon. The substrate 100 may be transparent and may have flexibility. The substrate 100 may be made of, for example, glass or a plastic material.

In an implementation of the present disclosure, the substrate 100 may be formed of multiple layers, and may be formed, for example, in a form in which an interlayer inorganic film is disposed between different flexible substrates.

In an implementation of the present disclosure, the substrate 100 includes emission areas EA1, EA2, and EA3 and transmissive areas TA spaced apart from each other, and the transmissive areas TA may be arranged such that they do not overlap components including a light-blocking metal material such as wiring lines including gate lines GL, data lines DL, and transistors, thereby increasing the pure transmittance of light passing through the substrate 100. Accordingly, an object or image located under the substrate 100 can be observed from the outside of the uppermost component of the substrate 100. On the other hand, the emission areas EA1, EA2, and EA3 includes the light-emitting element (ED) 150, and may overlap wiring lines including gate lines GL and data lines DL and a transistor TFT which are components beneath the light-emitting element 150. Here, the light-emitting element 150 is formed by sequentially laminating a first electrode 151 provided for each subpixel, an intermediate layer 152, and a second electrode 153. In the emission areas EA1, EA2, and EA3, light generated inside the light-emitting element 150 is emitted from the second electrode 153, and an image according to the operation of the light-emitting element can be observed from the outside of the uppermost component of the substrate 100.

The transistor TFT provided on the substrate 100 may include, for example, an active layer 125, a gate electrode 131 overlapping the active layer 125 with a second insulating film 122 interposed therebetween, a first source-drain electrode 132 and a second source-drain electrode 133 connected to both sides of the active layer 125. The active layer 125 may include a semiconductor material. The semiconductor material may be a silicon-based semiconductor material or an oxide-based semiconductor material.

A light-shielding pattern 115 may be further provided under the transistor TFT on the substrate 100, specifically, under the active layer 125. The light-shielding pattern 115 may block light from the lower side of the substrate 100 being transmitted to the transistor TFT, thereby preventing abnormal phenomena such as photocurrent generation.

A first insulating film 121 may be provided between the light-shielding pattern 115 and the active layer 125 on the substrate 100. The first insulating film 121 may serve as a buffer layer. The first insulating film 121 may have a function of preventing impurities included in the substrate 100 from being transferred to the active layer 125 and planarizing the surface on which the active layer 125 is formed. The first insulating film 121 may cover the light-shielding pattern 115. The first insulating film 121 may protect structures on the substrate 100 that are vulnerable to moisture penetration from moisture penetrating through the substrate 100 and planarize the surface of the substrate 100.

In some cases, one or more insulating films may be provided between the light-shielding pattern 115 and the substrate 100 to prevent impurities from entering the array on the substrate 100 from the substrate 100 and to additionally protect the array on the upper side of the substrate 100.

The first source-drain electrode 132 may be connected to the light-shielding pattern 115 in addition to being connected to the active layer 125 to stabilize the potential of the light-shielding pattern 115.

The second insulating film 122 between the active layer 125 and the gate electrode 131 may serve as a gate insulating film.

Third and fourth insulating films 123 and 124 may be provided between the gate electrode 131 and the first and second source-drain electrodes 132 and 133 for interlayer insulation. In the illustrated example, two insulating films are provided, but the present disclosure is not limited thereto. For example, a single insulating film may be provided between the gate electrode 131 and the first and second source-drain electrodes 132 and 133. Alternatively, three or more insulating films may be provided between the gate electrode 131 and the first and second source-drain electrodes 132 and 133.

The electrodes of the transistor TFT and the electrodes of the storage capacitor CS may be disposed on the same layer.

For example, when multiple inorganic films are provided between the gate electrode 131 and the first and second source-drain electrodes 132 and 133, a first storage electrode 127 may be disposed on the same layer as the gate electrode 131, and a second storage electrode 128 may be disposed on the third insulating film 123 covering the first storage electrode 127 and overlapping the first storage electrode 127.

The light-shielding pattern 115, the gate electrode 131, the first and second source-drain electrodes 132 and 133, and the first and second storage electrodes 127 and 128 may each include one of aluminum (Al), titanium (Ti), copper (Cu), chromium (Cr), molybdenum (Mo), and tungsten (W).

A plurality of transistors TFTs is provided in each subpixel, and some of the plurality of transistors may serve as switching transistors and others may serve as driving transistors. For different functions, a switching transistor and a driving transistor may have different lamination structures or may have different widths and/or lengths of active layer channels.

The second storage electrode 128 may have the same layer as one electrode of the transistor illustrated in FIG. 4 and FIG. 5 and other transistors.

The first to fourth insulating films 121, 122, 123, and 124 may each include an inorganic insulating film, for example, a silicon oxide (SiOx) film, a silicon nitride (SiNx) film, or a laminate thereof.

A first organic film 141 and a second organic film 142 that protect the transistor TFT and the storage capacitor CS may be provided on the fourth insulating film 124. In some cases, the second organic film 142 may be omitted.

The first organic film 141 may be disposed on the transistor TFT or on the fourth insulating film 124 to protect the transistor TFT and alleviate a step caused by the transistor TFT.

A connection electrode 135 or a shielding pattern may be further provided on the first organic film 141, corresponding to the circuit components of subpixels, such as the transistor TFT and the storage capacitor CS. The connection electrode 135 may serve to electrically connect the transistor TFT and the first electrode 151 of the light-emitting element 150. The shielding pattern may serve to prevent the operation of the circuit components disposed thereunder from causing electrical interference with the operation of the light-emitting element 150 disposed thereabove.

The first and second organic films 141 and 142 cover the transistor TFT and are disposed on the fourth insulating film 124 to provide a flat surface.

The first organic film 141 and the second organic film 142 may each include an organic material. The organic material may include one or more of acrylic resin, phenolic resin, polyimide resin, unsaturated polyester resin, polyamide resin, benzocyclobutene, polyphenylene resin, and polyphenylene sulfide resin.

In addition to the first to fourth insulating films 121, 122, 123, and 124 described above, various functional organic films or inorganic films may be additionally provided between the substrate 100 and the first organic film 141.

In the transmissive area TA, at least one of the first to fourth insulating films 121, 122, 123, and 124 and the first and second organic films 141 and 142 may be removed to reduce the path through which light propagates in the transmissive area TA, thereby increasing transparency. Although FIG. 5 shows an example in which the first and second organic films 141 and 142 are omitted in the transmissive area TA, the implementations of the present disclosure are not limited thereto. In the transmissive area TA, one of the first to fourth insulating films 121, 122, 123, and 124 may be omitted instead of the first and second organic films 141 and 142, or the first and second organic films 141 and 142 and one of the first to fourth insulating films 121, 122, 123, and 124 may be omitted together in the transmissive area TA.

The light-emitting element 150 is disposed on the second organic film 142. The light-emitting element 150 may be electrically connected to the transistor TFT through an organic film 140. The light-emitting element 150 includes a first electrode 151, an intermediate layer 152, and a second electrode 153.

The first electrode 151 may serve as an anode. The first electrode 151 may be connected to the transistor TFT by passing through the second organic film 142 and the first organic film 141. In the illustrated example, the connection electrode 135 is further provided between the first electrode 151 and the transistor TFT is shown, the transistor TFT and the connection electrode 135 are connected, and the connection electrode 135 and the first electrode 151 are connected, but the second source/drain electrode 133 of the transistor TFT and the first electrode 151 of the light-emitting element 150 may be directly connected without the connection electrode 135.

The first electrode 151 may include a metal material having high reflectivity. For example, the first electrode 151 may be formed in a multilayer structure such as a laminated structure of aluminum (Al) and titanium (Ti) (Ti/Al/Ti), a laminated structure of aluminum (Al) and ITO (ITO/Al/ITO), an APC (Ag/Pd/Cu) alloy, a laminated structure of an APC alloy and ITO (ITO/APC/ITO), or a laminated structure of silver (Ag) and molybdenum/titanium alloy (Ag/MoTI), or may include a single-layer structure made of one material selected from silver (Ag), aluminum (Al), molybdenum (Mo), gold (Au), magnesium (Mg), calcium (Ca), or barium (Ba), or two or more alloy materials. The first electrode 151 may be referred to as a reflective electrode.

The intermediate layer 152 is provided on the first electrode 151. The intermediate layer 152 may include a hole injection layer, a hole transport layer, an organic emission layer, an electron transport layer, and an electron injection layer.

The edge of the first electrode 151 may overlap with a bank 155. An area of the first electrode 151 exposed from the bank 155 may be an emission area EA1, EA2, and EA3.

When a voltage is applied to the first electrode 151 and the second electrode 153, holes and electrons move to the organic emission layer through the hole injection layer and the hole transport layer, and the electron injection layer and the electron transport layer, holes and electrons combine with each other to form excitons in the organic emission layer, and the excitons drop from an excited state to a ground state, causing light emission.

Each layer of the intermediate layer 152 may be provided in common throughout the entire active area AA. In some cases, one layer of the intermediate layer 152 may be selectively provided in the emission areas EA1, EA2, and EA3. The light-emitting element 150 may have a tandem configuration in which a plurality of stacks including an emission layer, a hole-transport common layer related to hole transport disposed under the emission layer, and an electron-transport common layer related to electron transport disposed under the emission layer is provided, and a charge generation layer is provided between the plurality of stacks as an intermediate layer configuration. In the tandem configuration, each layer including the charge generation layer of the intermediate layer 152 may be a common layer disposed on the overall surface of the active area AA.

The intermediate layer 152 may include at least one of a red emission layer emitting red light, a green emission layer emitting green light, or a blue emission layer emitting blue light. The red emission layer, the green emission layer, and the blue emission layer may be provided on the first electrode 151 for respective subpixels SP. The red emission layer may be disposed in a red subpixel, the green emission layer may be disposed in a green subpixel, and the blue emission layer may be disposed in a blue subpixel, but the present disclosure is not necessarily limited thereto and at least two organic emission layers among the red emission layer, the green emission layer, and the blue emission layer may be laminated and disposed in one subpixel SP.

The intermediate layer 152 may be a white emission layer emitting white light. In this case, the organic emission layer of the intermediate layer 152 may be a common layer that is commonly disposed in the subpixels SP rather than in a patterned form.

The second electrode 153 may be a common layer that is commonly disposed in the subpixels SP and supplied with the same voltage. To this end, the second electrode 153 may be disposed to extend from the active area AA to a part of the non-active area NA.

The second electrode 153 may be a light-transmitting electrode. The second electrode 153 may include a transparent conductive material such as indium tin oxide (ITO) or indium zinc oxide (IZO) that can transmit light, or a semi-transmissive conductive material such as magnesium (Mg), silver (Ag), or an alloy of magnesium (Mg) and silver (Ag). When the second electrode 153 includes a trans-reflective material having both transparency and reflectivity, the light emission efficiency can be increased by the microcavity effect. When the second electrode 153 includes a semi-transmissive conductive material, the second electrode 153 may be thin sufficiently to transmit light. For example, the thickness of the second electrode 153 may be 200 Å or less.

The first electrode 151 may prevent light generated in the intermediate layer 152 from being transmitted to a light-shielding component below the first electrode 151 by including a reflective electrode. The light generated in the intermediate layer 152 resonates between the second electrode 153 and the first electrode 151, and can finally be emitted upward through the second electrode 153. Since the first electrode 151 includes a reflective component, even if the first electrode 151 overlaps with wiring lines and the transistor TFT, light emitted from the light-emitting element 150 is visible in the emission areas EA1, EA2, and EA3 without being affected by the arrangement of the wiring lines and the transistor TFT.

The intermediate layer 152 and the second electrode 153 among the components of the light-emitting element 150 may be independently disposed in the transmissive area TA.

The transmissive area TA does not have the first electrode 151 compared to the emission areas EA1, EA2, and EA3. The intermediate layer 152 and the second electrode 153 may be provided independently in the transmissive area TA. At least one of the hole injection layer, the hole transport layer, the electron transport layer, and the electron injection layer of the intermediate layers 152 may extend laterally from the emission areas EA1, EA2, and EA3 and may be provided in the transmissive area TA. As shown in FIG. 4 and FIG. 5, the second electrode 153 may be provided in the transmissive area TA. In some cases, the second electrode 153 may be omitted from the transmissive area TA to increase the transmittance of the transmissive area TA.

When the intermediate layer 152 and the second electrode 153 are provided in the transmissive area TA, the use of a fine metal mask (FMM) requiring a fine opening at the time of forming each layer can be omitted, and yield improvement and process simplification are expected.

The encapsulation layer 160 is provided on the light-emitting element 150 to protect and seal the light-emitting element.

The encapsulation layer 160 may be provided as a single film or as a multilayer film. When the encapsulation layer 160 is a multilayer film, for example, an inorganic encapsulation layer and an organic encapsulation layer may be disposed in an alternating form. The uppermost film and the lowermost film of the encapsulation layer 160 may be inorganic encapsulation layers, which is advantageous in preventing external air such as moisture from penetrating.

The encapsulation layer 160 planarizes the surface unevenness of the light-emitting element 150. Accordingly, the touch sensor 170 provided on the encapsulation layer 160 and detecting an external touch is disposed on the flat encapsulation layer 160.

The touch sensor 170 may include a touch buffer film 171 disposed on the encapsulation layer 160, a first wiring layer 172 disposed on the touch buffer film 171, a touch insulating film 173 covering the first wiring layer 172 and planarizing the surface, a second wiring layer 174 disposed on the touch insulating film 173 and connected to a part of the first wiring layer 172, and a touch protection film 175 disposed on the second wiring layer 174 and providing a flat surface of the color filter array. In some cases, either the touch buffer film 171 or the touch protection film 175 may be omitted.

The touch buffer film 171, the touch insulating film 173, and the touch protection film 175 may be inorganic films made of silicon oxide (SiOx), silicon nitride (SiNx), or silicon oxynitride (SiOxNy), or organic films made of acrylic resin, epoxy resin, ester-based resin, polyimide-based resin, or polyamide-based resin.

The color filter array 180 may be provided on the touch sensor 170. The color filter array 180 can include a light-shielding layer 181 and color filters 182 (182a, 182b, and 182c). The light-shielding layer 181 is disposed in an area other than the emission areas EA1, EA2, and EA3 and other than the transmissive area TA. The color filters 182 (182a, 182b, and 182c) are disposed to correspond to the emission areas EA1, EA2, and EA3. The light-shielding layer 181 and the color filters 182 (182a, 182b, and 182c) included in the color filter array 180 may serve to absorb external light coming from above toward the display device 1000, thereby preventing reflection of the external light by the metals of the touch sensor 170 and the light-emitting element 150. In this case, the color filter array 180 disposed on the touch sensor 170 can replace a polarizing plate, and thus the polarizing plate positioned above the light-emitting element in the display device 1000 can be omitted, thereby achieving a slim and simplified structure of the display device.

The light-shielding layer 181 may be disposed to cover at least the area occupied by the first wiring layer 172 and the second wiring layer 174 of the touch sensor 170, thereby preventing external light from being transmitted to the first wiring layer 172 and the second wiring layer 174 and preventing glinting due to the wiring layers of the touch sensor 170. The first wiring layer 172 and the second wiring layer 174 are disposed in the area between emission areas, between transmissive areas, and between the emission area and a transmissive area, and are covered by the light-shielding layer 181.

The emission area EA may include, for example, the first to third emission areas EA1, EA2, and EA3. The color filter 182 may include the first color filter 182a disposed in the first emission area EA1, the second color filter 182b disposed in the second emission area EA2, and the third color filter 182c disposed in the third emission area EA3. The first to third emission areas EA1, EA2, and EA3 may include emission layers emitting different colors in the intermediate layer 152 and thus emit different colors. In this case, the color filter 182 may transmit the color emitted from the corresponding emission area more clearly. Alternatively, the light-emitting element 150 included in each of the first to third emission areas EA1, EA2, and EA3 may emit white light, and transmit light of a color corresponding to each emission area through the color filter 182 in the color filter array 180 above the touch sensor 170. When the light-emitting element emits white light, the intermediate layer 152 may be formed in a form in which a plurality of stacks including emission layers emitting a plurality of different colors is laminated.

The color filters 182a, 182b, and 182c overlap the entire emission areas EA1, EA2, and EA3 and have edges that protrude further outward than the edges of the emission areas EA1, EA2, and EA3. These edges of the color filters 182a, 182b, and 182c overlap a part of the light-shielding layer 181 located outside the emission areas EA1, EA2, and EA3. The color filters 182a, 182b, and 182c may partially overlap the bank 155 between the emission areas EA1, EA2, and EA3, as shown in FIG. 4. Therefore, the color filters 182a, 182b, and 182c between the emission areas EA1, EA2, and EA3 overlap with the light-shielding layer 181, thereby preventing light leakage and blocking light coming from the upper side to the side and light emitted from each of the emission areas EA1, EA2, and EA3 and traveling in the oblique direction to adjacent subpixels, thereby enabling viewing angle light shielding.

The color filter array 180 may further include an upper insulating film 183 that compensates for the surface step between the light-shielding layer 181 and the color filters 182a, 182b, and 182c and planarizes the upper surface. The upper insulating film 183 is a transparent insulating film and may be an inorganic film or an organic film. In some cases, the upper insulating film 183 may be a multilayer film. The upper insulating film 183 may serve as a cover film that protects the lower components at the outermost side of the display device 1000.

In the display device according to an implementation of the present disclosure, the emission areas EA1, EA2, and EA3 and the transmissive areas TA are spaced apart from each other on a plane, as shown in FIG. 3.

In the display device according to an implementation of the present disclosure, the emission areas EA1, EA2, and EA3 emitting different lights may be spaced apart from each other, and the transmissive areas TA may be spaced apart from each other. In addition, each of the emission areas EA1, EA2, and EA3 may be disposed between the transmissive areas TA and spaced apart from the transmissive areas TA.

Referring to FIG. 3, in the display device according to an implementation of the present disclosure, the transmissive areas TA may be disposed in one row with the data line DL interposed therebetween, and the emission areas EA1, EA2, and EA3 are disposed in the next row. That is, the rows of the transmissive areas TA and the rows of the emission areas EA1, EA2, and EA3 are arranged alternately. This is an example, and in some cases, the emission areas may be disposed in a row where the transmissive areas are disposed, overlapping the area where wiring lines between the transmissive areas are located in other implementations of the present disclosure.

The transmissive areas TA are areas that do not overlap wiring lines such as the gate line GL and the data line DL, and differs from the emission areas EA1, EA2, and EA3 that overlap at least one wiring line. In addition to the gate line GL and the data line DL illustrated in FIG. 3, wiring lines may include the first power voltage line for supplying the low-level voltage EVSS or a common voltage included in the subpixel of FIG. 2, and the second power voltage line for supplying the high-level voltage EVDD.

The area excluding the transmissive areas TA may be a non-transmissive area NTA, and the non-transmissive area NTA may include an area overlapping with the emission areas EA1, EA2, and EA3 and an area that does not overlap with the emission areas EA1, EA2, and EA3. The bank 155 may be disposed in the area of the non-transmissive area NTA that does not overlap with the emission areas EA1, EA2, and EA3.

The bank 155 may have openings corresponding to the transmissive areas TA and the emission areas EA1, EA2, and EA3. The edge of the first electrode 151 of the light-emitting element 150 may overlap with the bank 155, and areas of the first electrode 151 exposed from the bank 155 may become the emission areas EA1, EA2, and EA3.

In FIG. 3, the first and third emission areas EA1 and EA3 are illustrated as octagons, and the second emission area EA2 is illustrated as a square, but the implementation of the present disclosure is not limited thereto. In addition to an octagon or a square, the emission areas EA1, EA2, and EA3 may be a polygon including a hexagon, a decagon, a dodecagon, etc., or may be an area having a round portion. Each of the emission areas EA1, EA2, and EA3 may have a side parallel to a side of another adjacent emission area and a side of the transmissive area TA.

The display device 1000 of the implementations of the present disclosure includes the touch sensor 170 and the color filter array 180 provided on the encapsulation layer 160 that protects the light-emitting element 150. Since the transmissive area TA is provided under the touch sensor 170, the first and second wiring layers 172 and 174 of the touch sensor 170 and the color filter array 180 are disposed to maximize the transmittance of the transmissive area TA.

The first and second wiring layers 172 and 174 of the touch sensor 170 include a metal component, have little resistance in transmitting a touch detection signal and a touch sensing signal, and may have a narrow line width. In the display device 1000 of the implementations of the present disclosure, the first and second wiring layers 172 and 174 of the touch sensor 170 include a metal component, and thus the first and second wiring layers 172 and 174 are disposed such that they do not overlap with the emission areas EA1, EA2, and EA3 and the transmissive area TA.

The second wiring layer 174 may be a plurality of spaced sensor layer electrodes that detect electrostatic capacitance that changes according to touch, and the first wiring layer 172, which is disposed in a different layer from the second wiring layer 174, may serve to electrically connect the spaced sensor layer electrodes of the second wiring layer 174.

In the implementations which will be described below, the first wiring layer 172 adjacent to the encapsulation layer 160 will be described as a bridge electrode layer, and the second wiring layer 174 located far from the encapsulation layer 160 will be described as a sensor electrode layer electrode, but the implementations of the present disclosure are not limited thereto. In another implementation of the present disclosure, the bridge electrode layer may be located on the upper side and the sensor electrode layer may be located on the lower side.

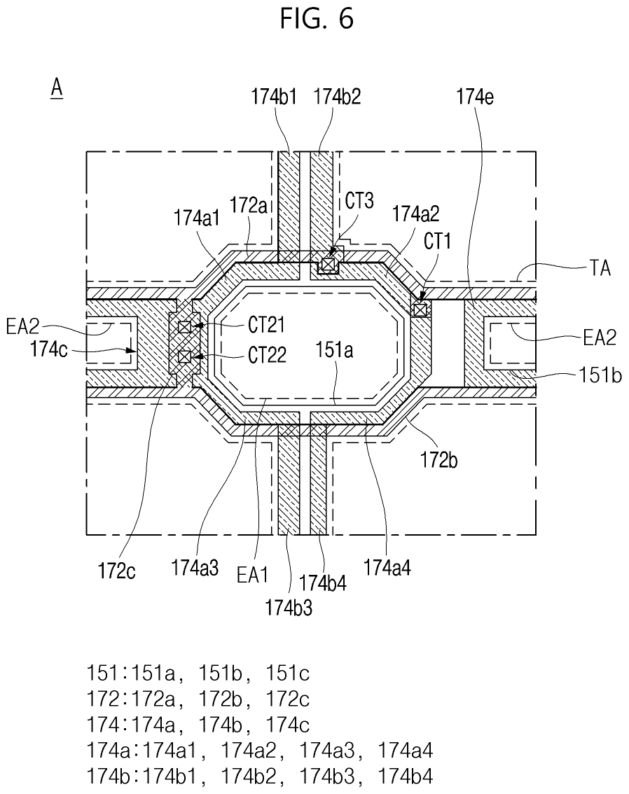

Referring to FIG. 3 and FIG. 6, the first wiring layer 172 may extend along the upper and lower edges of the plurality of emission areas EA1, EA2, and EA3 arranged in the same row. The first wiring layer 172 may have a line shape that extends in the horizontal direction in which the emission areas EA1, EA2, and EA3 are arranged outside of the emission areas EA1, EA2, and EA3 of FIG. 3.

Referring to FIG. 3 and FIG. 6, The second wiring layer 174 may be disposed in the column direction and may extend in the vertical direction intersecting the first direction with respect to the first and third emission areas EA1 and EA3. The area where the first and second wiring layers 172 and 174 are disposed overlaps with the bank 155.

The bank 155 may include at least one of a black material, a light-shielding material, and a light-absorbing material. The light-shielding layer 181 and the bank 155 can effectively prevent light from traveling in the oblique direction from the emission areas EA1, EA2, and EA3 and light from traveling in the oblique direction from above by shielding them together, thereby achieving viewing angle light shielding.

In an implementation of the present disclosure, contact holes in the first wiring layer 172 and the second wiring layer 174 may be disposed adjacent to a corner of one of the emission areas having a polygonal shape. At least a first contact hole CT1 for connection between the first and second wiring layers 172 and 174 is formed using the area where the first and second wiring layers 172 and 174 are disposed to overlap adjacent to one corner of an emission area, and thus a separate area does not need to be provided and the area of the transmissive area TA can be maximized. Meanwhile, since the sides of the emission area that extend in different directions meet each other at one corner of the emission area, the diameter of the area occupied by the wiring layers larger than that of the wiring layer area extending in a single direction can be secured.

The contact holes CT1, CT2 (CT21 and CT22), and CT3 of the first wiring layer 172 and the second wiring layer 174 may be disposed in the touch insulating film 173 between the first and second wiring layers 172 and 174, as shown in FIG. 3 to FIG. 5.

The display device according to the implementation of the present disclosure may have a regularity in which the transmissive area TA and the first and second wiring layers 172 and 174 of the touch sensor 170 are arranged such that they do not overlap with the first electrode 151 of the light-emitting element 150.

Hereinafter, the disposition of the contact holes of the first wiring layer 172 and the second wiring layer 174 based on the first emission area EA1 will be specifically described with reference to FIG. 6 to FIG. 8 and FIG. 3 to FIG. 5.

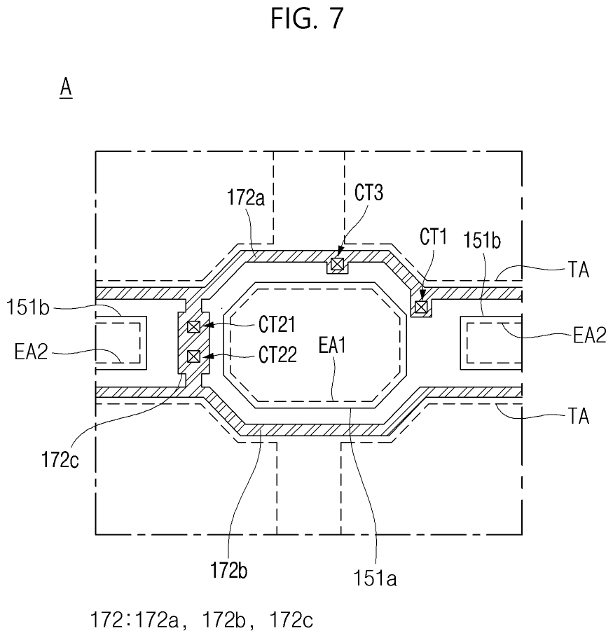

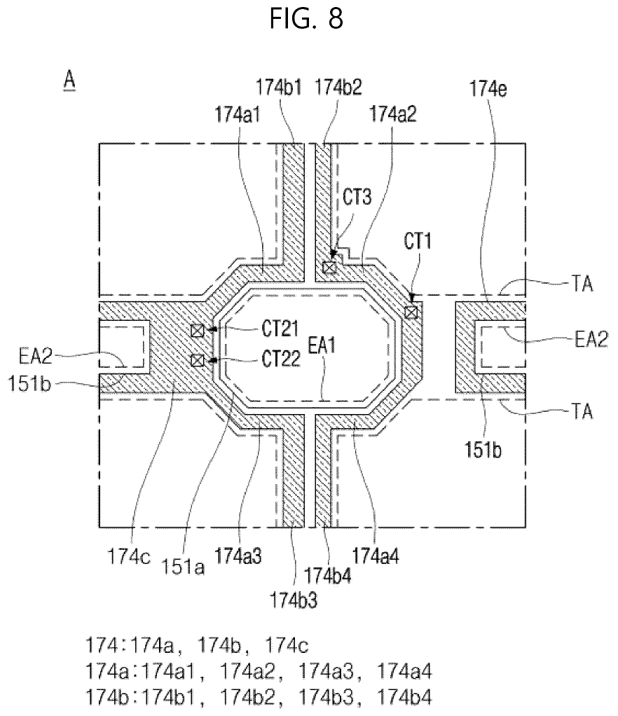

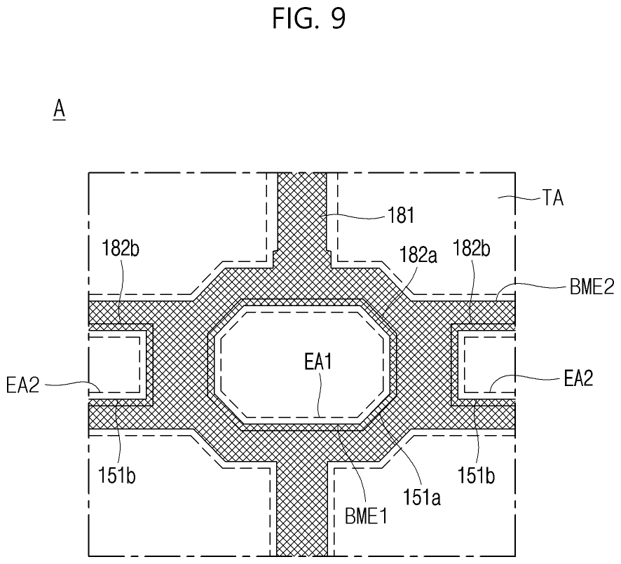

FIG. 6 is a plan view showing the touch sensor in area A in FIG. 3 according to an implementation of the present disclosure. FIG. 7 is a plan view showing the first wiring layer and contact holes in area A in FIG. 6. FIG. 8 is a plan view showing the second wiring layer and contact holes in area A in FIG. 6. FIG. 9 is a plan view showing the light-shielding layer and the color filter in area A in FIG. 6.

The area A in FIG. 3 shows the first emission area EA1, and the second emission area EA2 and transmissive areas around the first emission area EA1.

The touch sensor 170 includes the first wiring layer 172 and the second wiring layer 174 that include a metal material. In the display device according to the implementation of the present disclosure, the first wiring layer 172 and the second wiring layer 174 are disposed to overlap at least the light-shielding layer 181, and thus external light incident from above can be prevented from being directly transmitted to the first wiring layer 172 and the second wiring layer 174 and reflected. If the wiring layers of the touch sensor are exposed from the light-shielding layer, glinting caused by the wiring layers of the touch sensor may be visible.

The first wiring layer 172 and the second wiring layer 174 are disposed such that they do not overlap the emission areas EA1, EA2, and EA3 and the transmissive area TA. For example, the first wiring layer 172 and the second wiring layer 174 may be positioned between the plurality of emission areas EA1, EA2, and EA3, between the plurality of transmissive areas TA, and/or between at least one emission area and at least one transmissive area, as illustrated in FIG. 3.

The first wiring layer 172 and the second wiring layer 174 may overlap with the bank 155. The bank 155 is disposed around each of the emission areas EA1, EA2, and EA3 and the transmissive area TA. The bank 155 is provided in the part of the active area AA excluding the emission areas EA1, EA2, and EA3. As shown in FIG. 3, in a cross-shaped pattern in which the emission areas EA1, EA2, and EA3 corresponding to small-sized openings are disposed in a pattern having the transmissive area TA as a large opening. In the display device 1000, the transmittance may increase in proportion to the area of the transmissive area TA. In case of high transmittance, visibility of an image and an object under the substrate 100 can be higher.

In the display device 1000 according to an implementation of the present disclosure, the first wiring layer 172 of the touch sensor 170 may be a bridge electrode layer, and the second wiring layer 174 may a plurality of spaced sensor layer electrodes that detect touch. The first wiring layer 172 can connect adjacent sensor layer electrodes of the second wiring layer 174. The first wiring layer 172 and the second wiring layer 174 may be disposed in a line shape between the emission areas EA1, EA2, and EA3 and the transmissive areas TA.

As shown in FIG. 3, FIG. 6, and FIG. 7, the first wiring layer 172 may include a first bridge pattern 172a adjacent to the upper sides of the emission areas EA1, EA2, and EA3 in the same row, a second bridge pattern 172b adjacent to the lower sides of the emission areas EA1, EA2, and EA3 in the same row, and a third bridge pattern 172c connecting the first bridge pattern 172a and the second bridge pattern 172b between the adjacent emission areas EA1 and EA2.

In addition, the second wiring layer 174 may include a first sensor pattern 174a (174la1, 174a2, 174a3, and 174a4) disposed inside the first wiring layer 172, and a second sensor pattern 174b (174b1, 174b2, 174b3, and 174b4) extending from the first sensor pattern 174a (174a1, 174a2, 174a3, and 174a4) to intersect the first bridge pattern 172a or the second bridge pattern 172b. The second wiring layer 174 may further include a third sensor pattern 174c connected to the first sensor pattern 174a of the second wiring layer 174 and overlapping the third bridge pattern 172c between the adjacent first and second emission areas EA1 and EA2.

The second contact hole CT2 may be disposed in an area where the third bridge pattern 172c and the third sensor pattern 174c overlap.

The first sensor patterns 174a1 and 174a2 disposed along the upper side of the first emission area EA1 in the second wiring layer 174 may be spaced apart from each other between two adjacent transmissive areas TA. The first sensor patterns 174a1 and 174a2 spaced apart from each other may be supplied with an electrical signal without interruption along the upper side of the first emission area EA1 through the first bridge pattern of the first wiring layer 172 connected through the first contact hole CT1. The first sensor patterns 174a1 and 174a2 disposed along the upper side of the first emission area EA1 in the second wiring layer 174 may be respectively connected to the second sensor patterns 174b1 and 174b2 passing between adjacent transmissive areas TA. At least some of the second sensor patterns may further include the third contact hole CT3 connected with the first wiring layer 172 at an intersection passing through the first bridge pattern 172a1. The third contact hole CT3 may be disposed adjacent to one side of the first emission area EA1 and one edge (corner) of the transmissive area TA. Through the third contact hole CT3, the second wiring layer 174 may also transmit electrical signals in the vertical direction.

The first sensor patterns 174a3 and 174a4 disposed along the lower side of the first emission area EA1 in the second wiring layer 174 may be spaced apart from each other between two adjacent transmissive areas TA. The first sensor pattern 174a1 disposed on the upper side and the first sensor pattern 174a3 disposed on the lower side, which are arranged on the left side, can be electrically connected to each other through the third sensor pattern 174c that is integrally connected thereto. In addition, the first sensor pattern 174a3 on the lower side is electrically connected to the second sensor pattern 174b3 on the lower side. In addition, the first sensor pattern 174a2 on the upper side and the first sensor pattern 174a4 on the lower side, which are disposed on the right side, are integrally connected at the right side of the first emission area EA1, and the first sensor patterns 174a2 and 174a4 may be electrically connected.

The second sensor patterns 174b (174b1, 174b2, 174b3, and 174b4) intersect the first bridge pattern 172a1 and the second bridge pattern 172a2, extend in the upper and lower directions, and form a vertical electrical connection.

Meanwhile, in the display device according to the implementation of the present disclosure, the first to third contact holes CT1, CT2, and CT3 are disposed asymmetrically, and thus the area where the first and second wiring layers overlap is not concentrated on a specific region in the area where the contact holes are located. Accordingly, it is possible to prevent the moiré phenomenon that occurs when metallic wiring layers are concentrated.

Based on the emission area EA1, the second wiring layer 174 can be supplied with an electrical signal in the horizontal direction without interruption along the upper side of the first emission area EA1 through the first bridge pattern 172a of the first wiring layer 172 connected through the first contact hole CT1 and the third contact hole CT3. In addition, the second wiring layer 174 may be electrically connected along with the first wiring layer 172 between the upper and lower sides of the first emission area EA1 through the second contact hole CT21 and CT22.

Meanwhile, the first sensor pattern 174a, the second sensor pattern 174b, and the third sensor pattern 174c of the second wiring layer 174 may be supplied with the same touch detection signal. A sensor pattern 174e surrounding the second emission area EA2 in the second wiring layer 174 is electrically separated from the first, second, and third sensor patterns 174a, 174b, and 174c surrounding the first emission area EA1, and a touch detection signal is applied to the sensor pattern 174e at a different point in time from the point in time when the touch detection signal is applied to the first, second, and third sensor patterns 174a, 174b, and 174c surrounding the first emission area EA1. The sensor pattern 174e surrounding the second emission area EA2 can detect a different touch area from that detected by the first to third sensor patterns 174a, 174b, and 174c of the second wiring layer 174 surrounding the first emission area EA1.

The first wiring layer 172 and the second wiring layer 174 may be disposed such that they do overlap in an area excluding the contact holes and intersections for connection. Therefore, by arranging the first wiring layer 172 and the second wiring layer 174 which are disposed on different layers such that they do not overlap, parasitic capacitance in addition to capacitance due to touch can be prevented, and the sensitivity of touch sensing can be increased.

The first wiring layer 172 and the second wiring layer 174 may be formed in a single-layer or multilayer structure using a metal having high corrosion resistance and acid resistance and high conductivity, such as aluminum (Al), titanium (Ti), copper (Cu), and molybdenum (Mo).

In addition, the touch sensor 170 may include the first contact hole CT1 adjacent to a corner of at least one polygonal emission area among the plurality of emission areas EA1, EA2, and EA3 and located between the first wiring layer 172 and the second wiring layer 174 for electrical connection between the first wiring layer 172 and the second wiring layer 174 disposed on different layers.

With respect to the first emission area EA1, the first contact hole CT1 is disposed between the first emission area EA1 and the adjacent transmissive area TA, and is positioned adjacent to or in contact with one corner of the first emission area EA1 and one corner of the transmissive area TA. The first contact hole CT1 adjacent to or in contact with one corner of the first emission area EA1 and one corner of the transmissive area TA is positioned adjacent to a bent portion of other sides of the first emission area EA1 extending in different directions, and the area of the bent portion can be used for the first contact hole CT1. Accordingly, the space between the first and second wiring layers 172 and 174 can be prevented from increasing, and the area of the transmissive area TA can be increased around the first contact hole CT1 occupied by the first and second wiring layers 172 and 174.

In addition, second contact holes CT21 and CT22 may be provided between the first emission area EA1 and the second emission area EA2 asymmetrically with the first contact hole CT1. As illustrated, two second contact holes CT21 and CT22 may be provided corresponding to one side of the first emission area EA1, but the present disclosure is not limited thereto. As another example, one second contact hole may be provided corresponding to one side of the first emission area EA1, and in some cases, three or more second contact holes may be provided. The number of second contact holes may be determined in consideration of the area of the space between the first and second emission areas EA1 and EA2.

Here, the second contact hole CT2 (CT21 and CT22) may be disposed between two adjacent emission areas EA1 and EA2 among the plurality of emission areas on the plane.

The first contact hole CT1, the second contact hole CT2, and the third contact hole CT3 may be located within at least one touch insulating film 173 between the first wiring layer 172 and the second wiring layer 174, and the first wiring layer 172 or the second wiring layer 174 may be filled in the contact holes and come into contact with the at least one touch insulating film 173 laterally. Here, the wiring layer 172 or 174 within the contact holes CT1, CT2, and CT3 in the touch insulating film 173 can block light transmitted laterally by the first wiring layer 172 or the second wiring layer 174 in the touch sensor 170.

The first wiring layer 172 and the second wiring layer 174 may be positioned between the plurality of emission areas EA1, EA2, and EA3, between the plurality of transmissive areas TA, and/or between at least one emission area EA1, EA2, or EA3 and at least one transmissive area TA on the plane.

The first wiring layer 172 may be a bridge electrode layer, and the second wiring layer 174 may be a sensor electrode layer.

The second wiring layer 174 does not overlap the first wiring layer 172 in an area except for the contact holes and the intersection with the first wiring layer 172 and disposed having a reduced parasitic capacitance, thereby improving touch characteristics.

The wiring layer area including the first sensor patterns 174a (174a1, 174a2, 174a3, and 174a4) of the first wiring layer 172 and the second wiring layer 174 may surround the emission areas EA1, EA2, and EA3 in the same row.

The light-shielding layer 181 may overlap both the wiring layer area including the first wiring layer 172 and the second wiring layer 174 and the area between the first wiring layer 172 and the second wiring layer 174.

The light-shielding layer 181 may have an edge that is farther outside than the wiring layer area including the first wiring layer 172 and the second wiring layer 174. For example, if the first wiring layer 172 is farther outside in the area between an emission area and a transmissive area, the light-shielding layer 181 may have an edge farther outside than the edge of the first wiring layer 172, and if the second wiring layer 174 is farther outside between emission areas, the light-shielding layer 181 may have an edge farther outside than the edge of the second wiring layer 174.

The color filter 182 (182a, 182b, and 182c may covers the entire area of the emission areas EA1, EA2, and EA3 and extend farther outward, and thus the edge thereof overlaps the wiring layer area including the first wiring layer 172 and the second wiring layer 174. Accordingly, even if misalignment occurs between the touch sensor 170 and the color filter array 180 disposed on the light-emitting element 150, the color filter 182 (182a, 182b, and 182c) that overlaps the light-shielding layer 181 can prevent light leakage due to the misalignment.

Contact holes may include, for at least one polygonal emission area among the emission areas EA1, EA2, and EA3, the first contact hole CT1 adjacent to one corner of the emission area EA1 and overlapping the first bridge pattern 172a and the first sensor pattern 174a, and the second contact hole CT2 overlapping the third bridge pattern 172c and the third sensor pattern 174c.

The contact holes may further include the third contact hole CT3 in a region where a portion of the first sensor pattern 174a bent to the second sensor pattern 174b overlaps with the first bridge pattern 172a.

The emission areas disposed in the same row may include at least different polygonal emission areas, and the second contact hole CT2 may be located between the different polygonal emission areas.

The first and third contact holes CT1 and CT3 are positioned between an emission area and a transmissive area at one corner of the emission area, and the second contact hole CT2 is positioned between adjacent emission areas, and thus the contact holes provided for the first and second wiring layers 172 and 174 do not occupy the area of the transmissive area, thereby maximizing the area of the transmissive area.

As shown in FIG. 9, the light-shielding layer 181 may be closer to the transmissive area TA than the first wiring layer 172 and the second wiring layer 174.

The light-shielding layer 181 may be closer to the emission area than the first wiring layer 172 or the second wiring layer 172.

In the display device according to the implementations of the present disclosure, when the touch sensor 170 and the color filter array 180 are disposed on the substrate including both the transmissive areas TA and emission areas EA1, EA2, and EA3, the wiring layers 172 and 174 of the touch sensor 170 do not overlap the transmissive areas, and the light-shielding layer 181 of the color filter array 180 covers the wiring layers 172 and 174 of the touch sensor 170, thereby maximizing the area of the transmissive areas TA and at the same time preventing glinting caused by the wiring layers of the touch sensor.

The display device according to the implementations of the present disclosure can prevent parasitic capacitance due to overlapping of the wiring layers 172 and 174 in addition to electrostatic capacitance due to touch by disposing the wiring layers 172 and 174 of the touch sensor 170 such that they do not overlap in an area excluding the contact holes CT1, CT2, and CT3 and intersections, thereby improving the sensing sensitivity.

The display device according to the implementations of the present disclosure can secure the maximum area of the transmissive area by locating the contact holes between the wiring layers 172 and 174 of the touch sensor 170 at one corner of the emission areas EA1, EA2, and EA3 having a polygonal shape.

In the display device according to the implementations of the present disclosure, the edge of the light-shielding layer 181 on the touch sensor 170 is farther outside than the edges of the wiring layers 172 and 174 of the touch sensor 170 and farther inside than the edge of the first electrode 151 of the light-emitting element 150, and thus the light-shielding layer can block slanted light transmitted from one of the emission areas EA1, EA2, and EA3 to an adjacent emission area.

In the display device according to the implementations of the present disclosure, the color filter array 180 includes the light-shielding layer 181 and the color filter 182 and serves as an anti-reflection film that prevents reflection of external light, and thus a polarizing plate can be omitted. In addition, the color filter corresponding to an emission area overlaps the light-shielding layer disposed outside the emission area by a certain line width, and thus light leakage due to misalignment can be prevented when the touch sensor and the color filter array are formed after the light-emitting element is formed.

In the display device according to the implementations of the present disclosure, contact hole positions of the wiring layers of the touch sensor disposed on the encapsulation layer and the arrangement of the color filter array are defined in relation to emission areas and transmissive areas without additional processes, and thus greenhouse gas emission due to the additional processes can be eliminated and process optimization can be implemented, achieving ESG (Environmental/Social/Governance) effects.

A display device according to one implementation of the present disclosure may comprise a substrate having a plurality of emission areas and a plurality of transmissive areas spaced apart from each other, a light-emitting element on the substrate, an encapsulation layer on the light-emitting element, a touch sensor on the encapsulation layer, the touch sensor including a first wiring layer and a second wiring layer that do not overlap with the emission areas and the transmissive areas and are located at different layers, a light-shielding layer on the touch sensor, the light-shielding layer overlapping the first wiring layer and the second wiring layer and a color filter on the touch sensor, and the color filter overlapping a portion of the light-shielding layer at an outside of the emission areas.

In a display device according to one implementation of the present disclosure, the touch sensor may be located at a corner of at least one emission area having a polygonal shape among the of emission areas and includes a first contact hole located between the first wiring layer and the second wiring layer.

In a display device according to one implementation of the present disclosure, the touch sensor may further include a second contact hole asymmetrical with the first contact hole with respect to at least one emission area having a polygonal shape among the emission areas and adjacent to one side of the at least one emission area. The first contact hole may be disposed at a corner of a side different from the side where the second contact hole is disposed.

In a display device according to one implementation of the present disclosure, the second contact hole may be disposed between two adjacent emission areas among the plurality of emission areas on a plane.

In a display device according to one implementation of the present disclosure, the first contact hole or the second contact hole may be located within at least one touch insulating film between the first wiring layer and the second wiring layer. The first wiring layer or the second wiring layer may be filled in the first contact hole or the second contact hole and may be in contact with the at least one touch insulating film laterally.

In a display device according to one implementation of the present disclosure, the first contact hole may be disposed at a corner of the transmissive area.

In a display device according to one implementation of the present disclosure, the first wiring layer and the second wiring layer may be positioned in at least one of an area between the emission areas, an area between the transmissive areas, and an area between at least one of the emission areas and at least one of the transmissive areas on a plane.

In a display device according to one implementation of the present disclosure, the first wiring layer may be a bridge electrode layer, and the second wiring layer may be a sensor electrode layer.

In a display device according to one implementation of the present disclosure, with respect to emission areas disposed in the same row among the emission areas, the first wiring layer may include a first bridge pattern adjacent to upper sides of the emission areas disposed in the same row, a second bridge pattern adjacent to lower sides of the emission areas disposed in the same row, and a third bridge pattern connecting the first bridge pattern and the second bridge pattern between adjacent emission areas, and the second wiring layer may include a first sensor pattern disposed inside the first wiring layer, and a second sensor pattern extended from the first sensor pattern to intersect the first bridge pattern or the second bridge pattern.

In a display device according to one implementation of the present disclosure, the second wiring layer may not overlap the first wiring layer in an area excluding a contact hole and an intersection with the first wiring layer.

In a display device according to one implementation of the present disclosure, a wiring layer area including the first wiring layer and the first sensor pattern of the second wiring layer may surround the emission areas in the same row.

In a display device according to one implementation of the present disclosure, the light-shielding layer may overlap both a wiring layer area including the first wiring layer and the second wiring layer and an area between the first wiring layer and the second wiring layer at an outside of both of the plurality of emission areas and the plurality of transmissive areas.

In a display device according to one implementation of the present disclosure, the light-shielding layer may have an edge farther outside than an edge of the wiring layer area, or the color filter may overlap the emission areas and an edge of the color filter overlaps the wiring layer area.

In a display device according to one implementation of the present disclosure, with respect to the at least one emission area having a polygonal shape, the first contact hole may overlap the first bridge pattern and the first sensor pattern, and the second contact hole may overlap the third bridge pattern and is disposed at another side that is not adjacent to the corner of the at least one emission area having a polygonal shape at which the first contact hole is located.

A display device according to one implementation of the present disclosure may further comprise a third contact hole in an area where a portion of the first sensor pattern bent to the second sensor pattern overlaps the first bridge pattern.

In a display device according to one implementation of the present disclosure, the first contact hole and the third contact hole may be located between the emission area having the polygonal shape and at least one of the plurality of transmissive areas, and the second contact hole may be located between emission areas having different polygonal shapes.

In a display device according to one implementation of the present disclosure, the light-shielding layer may be closer to the transmissive area than the first wiring layer and the second wiring layer, or the light-shielding layer may be closer to the emission area than the first wiring layer or the second wiring layer.

In a display device according to one implementation of the present disclosure, the light-emitting element may include a first electrode disposed at each of the emission areas, an emission layer on the first electrode, and a second electrode on the emission layer.

A display device according to one implementation of the present disclosure may further comprise a bank between the emission areas, between the transmissive areas, and between at least one of the emission areas and at least one of the transmissive areas. The bank may be in contact with an edge of the first electrode disposed at the emission areas.

In a display device according to one implementation of the present disclosure, the bank may include at least one of a black material, a light-shielding material, and a light-absorbing material.

In a display device according to one implementation of the present disclosure, the bank overlaps the light-shielding layer

With respect to each of the emission areas, an edge of a lower part of the bank may overlap the light-shielding layer and is positioned farther outside than an edge of the light-shielding layer.

In the display device according to the implementations of the present disclosure, when the touch sensor and the color filter array are disposed on the substrate including both the transmissive areas TA and emission areas, the wiring layers of the touch sensor do not overlap the transmissive areas, and the light-shielding layer of the color filter array covers the wiring layers of the touch sensor, thereby maximizing the area of the transmissive areas and at the same time preventing glinting caused by the wiring layers of the touch sensor.

The display device according to the implementations of the present disclosure can prevent parasitic capacitance due to overlapping of the wiring layers in addition to electrostatic capacitance due to touch by disposing the wiring layers of the touch sensor such that they do not overlap in an area excluding the contact holes and intersections, thereby improving the sensing sensitivity.

The display device according to the implementations of the present disclosure can secure the maximum area of the transmissive area by locating the contact holes between the wiring layers of the touch sensor at one corner of the emission areas having a polygonal shape.

In the display device according to the implementations of the present disclosure, the edge of the light-shielding layer 181 on the touch sensor is farther outside than the edges of the wiring layers of the touch sensor and farther inside than the edge of the first electrode of the light-emitting element, and thus the light-shielding layer can block slanted light transmitted from one of the emission areas EA1, EA2, and EA3 to an adjacent emission area.

In the display device according to the implementations of the present disclosure, the color filter array includes the light-blocking layer and the color filter and serves as an anti-reflection film that prevents reflection of external light, and thus a polarizing plate can be omitted. In addition, the color filter corresponding to an emission area overlaps the light-shielding layer disposed outside the emission area by a certain line width, and thus light leakage due to misalignment can be prevented when the touch sensor and the color filter array are formed after the light-emitting element is formed.

In the display device according to the implementations of the present disclosure, contact hole positions of the wiring layers of the touch sensor disposed on the encapsulation layer and the arrangement of the color filter array are defined in relation to emission areas and transmissive areas without additional processes, and thus greenhouse gas emission due to the additional processes can be eliminated and process optimization can be implemented, achieving ESG (Environmental/Social/Governance) effects.

It will be apparent to those skilled in the art that various modifications and variations can be made in the present disclosure without departing from the spirit or scope of the present disclosure. Thus, it is intended that the present disclosure cover the modifications and variations of the present disclosure provided they come within the scope of the appended claims and their equivalents.

What is claimed is:

1. A display device comprising:
a substrate having a plurality of emission areas and a plurality of transmissive areas spaced apart from each other;
a light-emitting element on the substrate;
an encapsulation layer on the light-emitting element;
a touch sensor on the encapsulation layer, the touch sensor including a first wiring layer and a second wiring layer that do not overlap with the plurality of emission areas and do not overlap with the plurality of transmissive areas, the first wiring layer the second wiring layer located at different layers;
a light-shielding layer on the touch sensor, the light-shielding layer overlapping the first wiring layer and the second wiring layer; and
a color filter on the touch sensor, the color filter overlapping a portion of the light-shielding layer at an outside of the plurality of emission areas.

2. The display device of claim 1, wherein the touch sensor is located at a corner of at least one emission area having a polygonal shape among the plurality of emission areas and includes a first contact hole located between the first wiring layer and the second wiring layer.

3. The display device of claim 2, wherein the touch sensor further includes a second contact hole asymmetrical with the first contact hole with respect to at least one emission area having a polygonal shape among the plurality of emission areas and adjacent to one side of the at least one emission area, and
the first contact hole is disposed at a corner of a side different from the side where the second contact hole is disposed.

4. The display device of claim 3, wherein the second contact hole is disposed between two adjacent emission areas among the plurality of emission areas on a plane.

5. The display device of claim 3, wherein the first contact hole or the second contact hole is located within at least one touch insulating film between the first wiring layer and the second wiring layer, and the first wiring layer or the second wiring layer is filled in the first contact hole or the second contact hole and is in contact with the at least one touch insulating film laterally.

6. The display device of claim 2, wherein the first contact hole is disposed at a corner of a transmissive area among the plurality of transmissive areas.

7. The display device of claim 1, wherein the first wiring layer and the second wiring layer are positioned in at least one of an area between the plurality of emission areas, an area between the plurality of transmissive areas, and an area between at least one of the plurality of emission areas and at least one of the plurality of transmissive areas on a plane.

8. The display device of claim 1, wherein the first wiring layer is a bridge electrode layer, and the second wiring layer is a sensor electrode layer.

9. The display device of claim 1, wherein:
with respect to emission areas disposed in the same row among the plurality of emission areas,
the first wiring layer includes a first bridge pattern adjacent to upper sides of the emission areas disposed in the same row, a second bridge pattern adjacent to lower sides of the emission areas disposed in the same row, and a third bridge pattern connecting the first bridge pattern and the second bridge pattern between adjacent emission areas, and
the second wiring layer includes a first sensor pattern disposed inside the first wiring layer, and a second sensor pattern extended from the first sensor pattern to intersect the first bridge pattern or the second bridge pattern.

10. The display device of claim 9, wherein the second wiring layer does not overlap the first wiring layer in an area excluding a contact hole and excluding an intersection between the second wiring layer the first wiring layer.

11. The display device of claim 9, wherein a wiring layer area including the first wiring layer and the first sensor pattern of the second wiring layer surrounds the emission areas in the same row.

12. The display device of claim 9, wherein the light-shielding layer overlaps both a wiring layer area including the first wiring layer and the second wiring layer and an area between the first wiring layer and the second wiring layer at an outside of both of the plurality of emission areas and the plurality of transmissive areas.

13. The display device of claim 11, wherein:
the light-shielding layer has an edge that extends farther outwards from an edge of the wiring layer area, or
the color filter overlaps the at least one of the plurality of emission areas and an edge of the color filter overlaps the wiring layer area.

14. The display device of claim 9, wherein:
with respect to the at least one emission area having a polygonal shape,
a first contact hole overlaps the first bridge pattern and the first sensor pattern, and
a second contact hole overlaps the third bridge pattern and is disposed at another side that is not adjacent to the corner of the at least one emission area having a polygonal shape at which the first contact hole is located.

15. The display device of claim 14, further comprising a third contact hole in an area where a portion of the first sensor pattern bent to the second sensor pattern overlaps the first bridge pattern.

16. The display device of claim 15, wherein:
the first contact hole and the third contact hole are located between the emission area having the polygonal shape and at least one of the plurality of transmissive areas, and
the second contact hole is located between emission areas having different polygonal shapes.

17. The display device of claim 1, wherein:
the light-shielding layer is closer to at least one of the plurality of transmissive areas than the first wiring layer and the second wiring layer, or
the light-shielding layer is closer to at least one of the plurality of emission areas than the first wiring layer or the second wiring layer.

18. The display device of claim 1, wherein:
the light-emitting element includes a first electrode disposed at each of the plurality of emission areas, an emission layer on the first electrode, and a second electrode on the emission layer,
the display device further comprising a bank between the plurality of emission areas, between the plurality of transmissive areas, and between at least one of the plurality of emission areas and at least one of the plurality of transmissive areas,
wherein the bank is in contact with an edge of the first electrode disposed at the emission areas.

19. The display device of claim 18, wherein the bank includes at least one of a black material, a light-shielding material, and a light-absorbing material.

20. The display device of claim 18, wherein:
the bank overlaps the light-shielding layer, and
with respect to each of the plurality of emission areas, an edge of a lower part of the bank overlaps the light-shielding layer and is positioned farther outside than an edge of the light-shielding layer.
